(19) United States
(12) Patent Application Publication
(10) Pub. No.: US 2015/0316289 A1
(43) Pub. Date: Nov. 5, 2015

(54) SOLAR SPECTRUM SELECTIVE ABSORPTION COATING AND ITS MANUFACTURING METHOD

(71) Applicant: TAHOE TECHNOLOGIES, LTD., Grand Cayman Islands (KY)

(72) Inventors: Xiaodong XIANG, Danville, CA (US); Jing LIU, Beijing (CN); Hong WANG, Beijing (CN)

(73) Assignee: TAHOE TECHNOLOGIES, LTD., Grand Cayman Islands (KY)

(21) Appl. No.: 14/577,499

(22) Filed: Dec. 19, 2014

(30) Foreign Application Priority Data
Apr. 11, 2014 (CN) 201410145986.1

(51) Int. Cl. F24J 2/46; F24J 2/48; C23C 14/00; C23C 14/35; C23C 14/02

(52) U.S. Cl. CPC F24J 2/4652; C23C 14/35; C23C 14/022; C23C 14/0036; F24J 2/485

(57) ABSTRACT

A solar spectrum selective absorption coating is disclosed. The coating includes, from the substrate to the air interface: substrate 1, infrared reflective layer 2, semiconductor absorption layer 3 (Ge), and antireflection layer 4 formed by a higher refractive-index dielectric layer 41 and a lower refractive-index dielectric layer 42. The solar spectrum selective absorption coating has superior spectrum selectivity, with a steep transition zone between solar absorption and infrared reflection zones. It has a relatively high absorptance α in the solar spectrum range (0.3-2 μm), and a very low absorptance/emissivity ε in the infrared thermal radiation spectrum range (2-50 μm); its a/c ratio is significantly higher than current commercially available products, making it suitable for medium-temperature solar heat collectors using low-power optical concentration. The manufacturing process is simple and does not require complex deposition equipment, so it is suitable for low-cost large-scale production.

### BACKGROUND OF THE INVENTION

1. Field of the Invention

This invention relates to a solar spectrum selective absorption coating and its manufacturing method, and in particular, it relates to such a coating based on an antireflection layer—semiconductor—metal interference film system and its manufacturing method.

2. Description of the Related Art

Solar spectrum selective absorption coating is a key material in solar thermal energy conversion. On the one hand, it has relatively high absorptance in the solar energy spectrum range (0.3 μm-2.5 μm); on the other hand, it has relatively low absorptance, which is equal to emissivity numerically according to Kirchoff's law, in the infrared thermal radiation spectrum range (2.5 μm-50 μm), which suppresses heat dissipation due to infrared radiation. An important performance criterion that measures the selective absorption property of a material is the ratio of its absorptance for the solar energy spectrum a to its infrared emissivity ε(T), i.e., a/c.

Current solar energy selective absorption coating structures used in solar heat collectors generally have a substrate/metal base layer/solar energy absorption layer/surface antireflection layer. The metal base layer has a very high reflectance in the infrared range, which is the main factor for the low emissivity. The surface antireflection layer lowers the solar light reflection at the interface between air and the coating, to allow more solar energy to enter the absorption coating and increase heat collection efficiency. The solar energy absorption layer has a high absorptance in the solar energy spectrum range (0.3 μm-2.5 μm) and a low absorptance in the infrared thermal radiation range (2 μm-50 μm), so it is relatively transparent in the infrared thermal radiation range, which does not- impact the high reflectance of the metal base layer in the infrared range. The absorption layer can be one of the following categories based on the absorption mechanism: 1. dielectric-metal-dielectric interference absorption film system; 2. cermet formed by metal particles embedded in a dielectric matrix; and 3. semiconductor material which is absorptive of light energy above the band gap width Eg (corresponding to intrinsic absorption edge in the near-infrared range) and transparent to light energy below the band gap width Eg. If a rough surface structure of a particular scale is formed for the semiconductor, the absorptance for solar energy is enhanced by a light trapping effect.

For the first and second categories of solar energy absorption layers such as Al₂O₃—Mo—Al₂O₃, CrₓO_{y}, AlN—Al, TiNₓO_{y}, Al(Mo,W,Ni,Co)—Al₂O₃, etc., a common characteristics is that their absorption layer is primarily a metal state or metal-dielectric mixture state, their extinction coefficient in the infrared range is high, which adversely affects the emissivity of the metal infrared reflective layer of the coating structure; as a result, while the absorptance α for the solar spectrum is relatively high (typically above 90%), the infrared emissivity ε(T) is also relatively high (typically above 5% at 80° C.). Also, the transition zone from the solar energy absorption zone to the infrared reflection zone is relatively wide, so that the effective infrared emissivity ε(T) increase rapidly with temperature (to higher than 10% in the medium- and high-temperature range), and the ratio a/c is typically less than 10 (in the medium- and high-temperature range) to 20 (at 80° C.). Therefore, when these two categories of coating are used in heat collectors with low optical concentration, the photothermal conversion efficiency of the heat collector is relatively low at working temperatures above 200° C.

The third category of optical spectrum selective absorption layer, which is based on semiconductor intrinsic absorption, has extremely low extinction coefficient (almost zero) for incident light energy below Eg, and when its thickness is below 100 nm, it does not affect the heat emissivity of the entire coating system (the metal reflective layer), so very low effective emissivity (approximately 2%) can be obtained. For the spectrum range where the energy is above Eg (which is the majority of the solar spectrum), its extinction coefficient is high, offering a potential of high absorption. However, because its refractive index is significantly different from that of the air, the reflectance at the semiconductor/air interface is high. For example, the reflectance of Ge film (10-10000 nm) to solar light is 40-60%. U.S. Pat. No. 4252865 uses an amorphous Ge film of over 4 μm thick as an absorption layer; by using a surface roughening process, a needle shaped gap structure is formed with gap sizes comparable to the wavelength of visible light, to achieve a light trapping effect, so that the absorptance for the solar spectrum is as high as 97%. But this reference does not report the infrared emissivity of the layer. Moreover, the Ge film used in this device is relatively thick, increasing the material cost. Flordal et al (Vacuum, Vol. 27, No. 4, June 1977, page 399-402) report a selective absorption coating of “antireflection layer SiO (60 nm)—absorption layer Ge (20-40 nm)—infrared reflective layer Al” formed by evaporation techniques, which achieves an absorptance of 74-79% for the solar spectrum and an infrared emissivity of 1.2%. As is well known, for non-stoichiometric silicon oxide compound SiOₓ, the value of x can be within a range (0<x<2); to stably obtain x=1 in the preparation process, the coating process is difficult to control, but if the product deviates from the stoichiometric composition, absorption in the infrared region will increase. Thus, this design has the disadvantages that it is not suitable for large scale production and has poor thermal stability.

### SUMMARY OF THE INVENTION

An object of the present invention is to provide a solar spectrum selective absorption coating having an “infrared reflective layer—absorption layer (Ge)—antireflection layer” layer structure based on intrinsic absorption of semiconductor germanium. Its characteristics are: 1. The coating system has excellent spectral selectivity. The transition zone between absorption zone and reflection zone is steep; the emissivity ε is extremely low (below 2%), the absorptance α is relatively high (approximately 80%), so its a/c ratio is higher than currently available products (20-40), making it suitable for medium- to high-temperature solar heat collectors with low optical concentration. 2. By combining the optical band gap characteristics of amorphous germanium and the optical antireflection design, multiple reflections and absorptions of the solar light by the absorption layer Ge between the antireflection layer and the infrared reflection layer are achieved, which enables the thickness of the Ge layer to be reduced, saving material cost. 3. The antireflection layer uses stoichiometric dielectrics, its preparation process is mature and the thermal stability of its material properties is high, making it suitable for large-scale, low-cost production.

To achieve these and other advantages and in accordance with the purpose of the present invention, as embodied and broadly described, the present invention provides:

According to an embodiment of the present invention, a solar spectrum selective absorption coating comprises, in that order: a substrate, an infrared reflective layer, an absorption layer, and an antireflection layer. The substrate is made of glass, aluminum, copper, or stainless steel, etc. The infrared reflective layer is preferably made of Al, but can also be made of Cu, Au, Ag, Ni, Cr or other metal with high electrical conductivity. The absorption layer is made of semiconductor germanium (Ge). The antireflection layer is made of two stoichiometric dielectrics having descending refractive indices from absorption layer to air, where the inner layer of higher refractive index dielectric is preferably TiO₂ (n=2.3-2.5 at 550 nm), but can also be other stoichiometric dielectrics having refractive indices between 2.0-3.0, such as Bi₂O₃, CeO₂, Nb₂O₅, TeO₂, HfO₂, ZrO₂, Cr₂O₃, Sb₂O₃, Ta₂O₅, Si₃N₄, etc. The outer layer of lower refractive index dielectric is preferably SiO₂(90%)/Al₂O₃(10%) (n=1.4-1.5 at 550 nm), but can also be other stoichiometric dielectrics having refractive indices between 1.1-2.0, such as porous SiO₂, Al₂O₃, ThO₂, Dy₂O₃, Eu₂O₃, Gd₂O₃, Y₂O₃, La₂O₃, MgO, Sm₂O₃, etc. The thickness of the infrared reflective layer is 50 nm-200 nm, the thickness of the Ge absorption layer is 15 nm-50 nm, the thickness of the higher refractive index layer of the antireflection layer is 10 nm-60 nm and the thickness of the lower refractive index layer of the antireflection layer is 30 nm-130 nm.

To achieve the above objects, the following layers are coated in order on a glass, aluminum, copper or stainless steel substrate: infrared reflective layer (Cu, Au, Ag, Ni, Cr, etc., preferably Al), semiconductor germanium (Ge) absorption layer, higher refractive index stoichiometric dielectric layer (Bi₂O₃, CeO₂, Nb₂O₅, TeO₂, HfO₂, ZrO₂, Cr₂O₃, Sb₂O₃, Ta₂O₅, Si₃N₄, etc., preferably TiO₂), lower refractive index stoichiometric dielectric layer (porous SiO₂, Al₂O₃, ThO₂, Dy₂O₃, Eu₂O₃, Gd₂O₃, Y₂O₃, La₂O₃, MgO, Sm₂O₃, etc., preferably SiO₂). The above infrared reflective layer, absorption layer, and antireflection layer can be formed by any suitable process so long as the layers can be properly formed, including magnetron sputtering, electron beam or thermal evaporation, ion plating, chemical vapor deposition, etc.

Preferably, in the above mentioned fabrication process for solar spectrum selective absorption coating, the thickness of the substrate is about 0.2-10 mm, the thickness of the infrared reflective layer is about 80-120 nm, the thickness of the absorption layer is about 20-40 nm, the thickness of the higher refractive index TiO₂ layer of the antireflection layer is about 20-50 nm, and the thickness of the lower refractive index SiO₂ layer of the antireflection layer is about 50-110 nm.

Preferably, in the above mentioned fabrication process for solar spectrum selective absorption coating, the absorption layer is an amorphous Ge thin film; within the 350 nm-980 nm wavelength range, its refractive index is 3.4-4.9 and its extinction coefficient is 0.5-3.1; and within the 2 μm-25 μm wavelength range, its refractive index is 4.1-4.3 and its extinction coefficient is below 0.03.

Preferably, in the above mentioned fabrication process for solar spectrum selective absorption coating, the infrared reflective layer is aluminum; within the 350 nm-980 nm wavelength range, its refractive index is 0.4-1.8 and its extinction coefficient is 3.8-9.0; and within the 2 μm-25 μm wavelength range, its refractive index increases from 2.1 to 55 and its extinction coefficient increases from 15.8 to 106.

Preferably, in the above mentioned fabrication process for solar spectrum selective absorption coating, the antireflection layer is formed by two metal oxide dielectric layers having higher and lower refractive indices, respectively; specifically, an inner layer of higher refractive index TiO₂ dielectric layer and an outer layer of lower refractive index SiO₂ dielectric layer. Within the 350 nm-2500 nm wavelength range, the refractive index of the TiO₂ dielectric layer is 3.0-2.3 and its extinction coefficient is below 0.03, and the refractive index of the SiO₂ dielectric layer is 1.47-1.43 and its extinction coefficient is below 0.03.

Embodiments of the present invention have the following characteristics:

The solar spectrum selective absorption coating according to embodiments of the present invention utilizes intrinsic semiconductor Ge having a band gap width of 0.7 eV (optical absorption edge of approximately 1800 nm) as the absorption layer, to accomplish effective absorption of solar energy within a major portion of the solar spectrum (photons with energy above the band gap width Eg); due to the high transmittance of Ge in the infrared range (above 2.0 μm, photons with energy below the band gap width Eg), the infrared light, after transmitting through the absorption layer, will be reflected by the infrared reflective layer, thereby achieving super-low thermal emissivity. In addition, by using the antireflection layer made of oxides with higher to lower refractive indices above the absorption layer, the refractive indices from the Ge layer to the antireflection layer to air is progressively lower, which reduces the reflection of sun light at the surface of Ge which has a relatively high refractive index. This further increases the absorption of sun light by the Ge layer.

Embodiments of the present invention have the following additional characteristics:

a. For the infrared reflective metal layer, as compared to metals like Au, Ag, Cu etc. which have similar near-infrared radiation properties, the preferred metal Al has higher refractive index and higher extinction coefficient in the entire spectrum range (visible solar light range and infrared thermal radiation range); thus, while accomplishing low infrared radiation, the use of Al enhances the solar spectrum absorptance of the selective absorption coating.

b. The solar energy absorption layer is a single semiconductor Ge layer; as compared to a dielectric-metal-dielectric or a dielectric-metal composite type of absorption layer, it has the advantages of a single layer, simple fabrication process, high process stability, low demand on the deposition equipment, etc., making it suitable for large-scale low-cost production.

c. The main optical characteristics of the absorption layer are that in the 350 nm-980 nm wavelength range, which includes over 70% of the solar energy spectral distribution, the extinction coefficient of Ge is greater than 0.5; near 480 nm where the solar energy spectral distribution is the highest, the extinction coefficient is even higher. The combination of the absorption layer Ge, the surface antireflection layer and the infrared reflective layer Al, which has an absorption peak at 820 nm, gives rise to an overall absorptance of over 90% between 340-980 nm.

d. Preferably, the refractive index of the higher refractive index antireflection layer TiO₂ in the 350 nm-2500 nm wavelength range is between 3.0-2.3, and its extinction coefficient is 0-0.03. The refractive index of the lower refractive index antireflection layer SiO₂ in the 350 nm-2500 nm wavelength range is between 1.47-1.43, and its extinction coefficient is 0-0.03.

The above are general description of the embodiments; the preferred embodiment of infrared reflective layer (Al)—absorption layer (Ge)—antireflection layer (TiO₂/SiO₂) is described in more detail below, and with reference to the drawings.

### BRIEF DESCRIPTION OF THE DRAWINGS

FIG. 1 illustrates the structure of a solar spectrum selective absorption coating according to an embodiment of the present invention.

FIG. 2 shows the absorption spectra of a coating of the present embodiment and a conventional selective absorption coating.

FIG. 3 shows the infrared emissivity curves of a coating of the present embodiment and a conventional selective absorption coating at various temperatures.

FIG. 4 schematically illustrates a manufacturing method for a solar spectrum selective absorption coating according to an embodiment of the present invention.

### DETAILED DESCRIPTION OF THE PREFERRED EMBODIMENTS

To illustrates the purpose, technical schemes and effect of the present invention, by reference to the preferred embodiments and the drawings, the solar spectrum selective absorption coating and its manufacturing method, implementations as well as testing results are described in detail below.

Being one of the intrinsic semiconductors, Ge is well-known as a selective absorbing coating. But because its refractive index is significantly higher than that of the air, the solar reflectivity at the semiconductor/air interface is so high that it is rarely used in practice. In order to achieve high absorptance, the reflectance needs to be reduced. Although the above mentioned U.S. Pat. No. 4252865 and article by Flordal et al. describe using a Ge film as an absorption layer, their approaches of reducing the optical reflectance at the Ge/air interface have disadvantages discussed earlier. To solve these problems, embodiments of the present invention employs a two-layer antireflection film, including an inner layer with higher refractive index and an outer layer with lower refractive index, both stoichiometric, which makes the fabrication process easy to control and to repeat.

FIG. 1 illustrates the structure of a solar spectrum selective absorption coating according to an embodiment of the present invention. The solar spectrum selective absorption coating includes, sequentially, substrate 1, infrared reflective layer 2, absorption layer 3, and antireflection layer 4.

The substrate 1 may be a glass plate having a thickness of 0.5-10 mm; it can also use metals such as copper, aluminum or stainless steel with a thickness of 0.2-2 mm. To increase the surface activity of the substrate, the substrate is cleaned by mechanical cleaning followed by RF (radio frequency) plasma cleaning, to remove contaminants and oxidized layer on the substrate surface.

The infrared reflective layer 2 is disposed on the substrate. The function of the infrared reflective layer 2 is to reflect the incident light in the entire incident spectral range, in particular the infrared range, and more particularly infrared light above 2.5 μm. The infrared reflective layer 2 is formed of aluminum and has a thickness of 50-200 nm.

The absorption layer 3 is disposed on the infrared reflective layer, and is formed of semiconductor Ge with a thickness of 15 nm-50 nm. Main optical characteristics of the absorption layer are that in the 350 nm-980 nm wavelength range, which includes over 70% of the solar energy spectral distribution, the extinction coefficient of Ge is greater than 0.5; near 480 nm where the solar energy spectral distribution is the highest, the extinction coefficient is even higher.

The antireflection layer is formed by two metal oxide dielectric layers having descending refractive indices from inner layer to outer layer; specifically, an inner layer of higher refractive index is a TiO₂ dielectric layer and an outer layer of lower refractive index is a SiO₂ dielectric layer. The thickness of the TiO₂ dielectric layer is 10 nm-60 nm, and within the 350 nm-2500 nm wavelength range, its refractive index is 3.0-2.3 and its extinction coefficient is below 0.03. The thickness of the SiO₂ dielectric layer is 30 nm-130 nm, and within the 350 nm-2500 nm wavelength range, its refractive index is 1.47-1.43 and its extinction coefficient is below 0.03.

Preparation Method

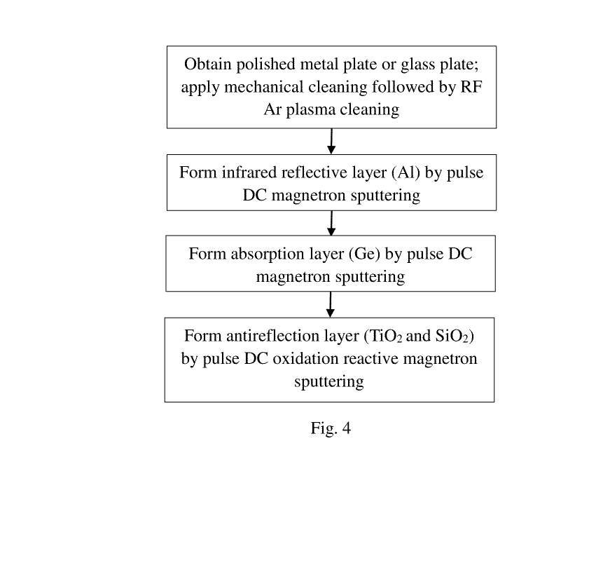

Embodiments of the present invention provides a preparation method for the above solar spectrum selective absorption coating, which includes the following steps (see FIG. 4):

Preparation of the substrate: Obtaining a polished metal plate or glass plate; applying mechanical cleaning, followed by RF Ar plasma cleaning to remove contaminants and oxidized layer on the substrate surface and increase surface activity of the substrate.

Formation of the infrared reflective layer: Using (pulse) DC magnetron sputtering to form a metal infrared reflective layer on the surface of the above mentioned substrate. The sputtering target can be metal Al (purity above 99.7%).

Formation of the absorption layer: Using (pulse) DC magnetron sputtering to form an absorption layer on the surface of the above mentioned infrared reflective layer. The sputtering target can be semiconductor Ge (purity above 99.7%).

Formation of the antireflection layer: Using (pulse) DC reactive magnetron sputtering to form an antireflection layer on the surface of the above mentioned absorption layer. The sputtering targets can be metal Ti (purity above 99.7%) and aluminosilicate (Al content 30% wt, purity above 99.7%).

### EXAMPLES

Table 1 lists the thickness of various single layers of a selective absorption coating based on semiconductor germanium intrinsic absorption formed by magnetron sputtering in one embodiment.

TABLE 1

| | Al layer/ | Ge layer/ | TiO₂ layer/ | SiO₂ layer/ |
|---|---|---|---|---|
| Sample | nm | nm | nm | nm |
| Embodiment | 150 | 25 | 31 | 71 |

The specific steps of the preparation process are as follows:

1) Cleaning of the glass plate: First, use a neutral wash solution to preliminarily clean the glass plate. Place the glass plate in the entrance chamber of the deposition equipment and perform second step cleaning using an RF plasma source to bombard the glass plate surface. The process parameters are as follows: RF source sputtering power is 200 w, working gas Ar (purity 99.99%) flow rate is 45 sccm, the working pressure is 9.8×10⁻² mTorr, and sputtering time is 360 s.

2) Pass the glass place from the entrance chamber to the sputtering chamber of the deposition equipment. The base pressure of the sputtering chamber is lower than 6×10⁻⁶ Torr.

3) Forming the infrared reflective layer Al on the substrate: Using pulse DC magnetron sputtering technique, bombard a metal Al target (purity 99.7%) to deposit a metal Al film on the glass substrate. The processing parameters are as follows: the pulse DC source's sputtering power is 1200 w, the working pressure is 5 mTorr, the working gas Ar (purity 99.99%) flow rate is 50 sccm, the transporting speed of the substrate is 0.8 m/min and the substrate is moved back and forth 5 times below the Al target, and the substrate temperature is room temperature.

4) Forming the absorption layer Ge on the Al/glass: Using pulse DC magnetron sputtering technique, bombard a Ge target (purity 99.7%) to deposit a Ge film on the Al/glass substrate. The processing parameters are as follows: the pulse DC source's sputtering power is 500 w, the working pressure is 3 mTorr, the working gas Ar (purity 99.99%) flow rate is 50 sccm, the transporting speed of the substrate is 1.3 m/min and the substrate is moved back and forth 2 times below the Ge target, and the substrate temperature is room temperature.

5) Forming the TiO₂ antireflection layer on the Ge/Al/glass: Using pulse DC oxidation reactive magnetron sputtering technique, bombard a Ti target (purity 99.7%) to deposit a TiO₂ layer on the Ge/Al/glass substrate. The processing parameters are as follows: the pulse DC source's sputtering power is 1000 w, the working pressure is 5 mTorr, the working gas Ar (purity 99.99%) flow rate is 50 sccm, the oxygen (purity 99.99%) flow rate is 8 sccm, the transporting speed of the substrate is 0.4 m/min and the substrate is moved back and forth 14 times below the Ti target, and the substrate temperature is room temperature.

6) Forming the SiO₂ antireflection layer on the TiO₂/Ge/Al/glass: Using pulse DC oxidation reactive magnetron sputtering technique, bombard an aluminosilicate target (Al content 30% wt, purity 99.7%) to deposit a SiO₂ layer on the TiO₂/Ge/Al/glass substrate. The processing parameters are as follows: the pulse DC source's sputtering power is 3000 w, the working pressure is 5 mTorr, the working gas Ar (purity 99.99%) flow rate is 30 sccm, the oxygen (purity 99.99%) flow rate is 14 sccm, the transporting speed of the substrate is 0.4 m/min and the substrate is moved back and forth 3 times below the aluminosilicate target, and the substrate temperature is room temperature.

7) After the above steps are completed, cool the sample for 20 min, and remove it from the deposition equipment.

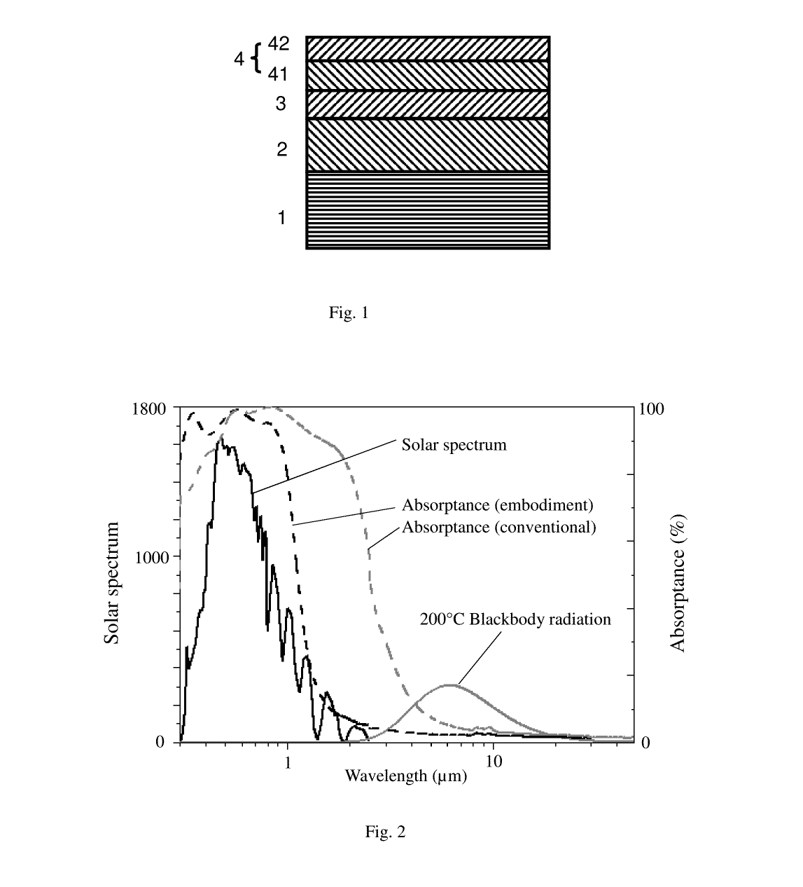

FIG. 2 shows the absorption spectra of a selective absorption coating of the present embodiment and a conventional selective absorption coating in the 0.3-48 μm wavelength range, as well as the solar spectrum and the radiation spectrum of a 200° C. blackbody. The 0.3-2.5 μm reflection spectra were measured using a Hitachi U-4100 spectrophotometer, and the 2.5-48 μm reflection spectra were measured using a Bruker Tensor27 Fourier transform infrared (FT-IR) spectrometer. From these measured spectra in the 0.3-48 μm range, it can be seen that compared to the conventional selective absorption coating, the selective absorption coating of the present embodiment has a steeper absorption-reflection transition zone, higher absorptance α in the solar spectrum range (0.3-2.5 μm), much lower emissivity ε in the thermal radiation infrared range (2-50 μm). Thus, its a/c ratio is higher than current commercially available products, making it suitable for medium-temperature solar heat collectors using low-power optical concentration.

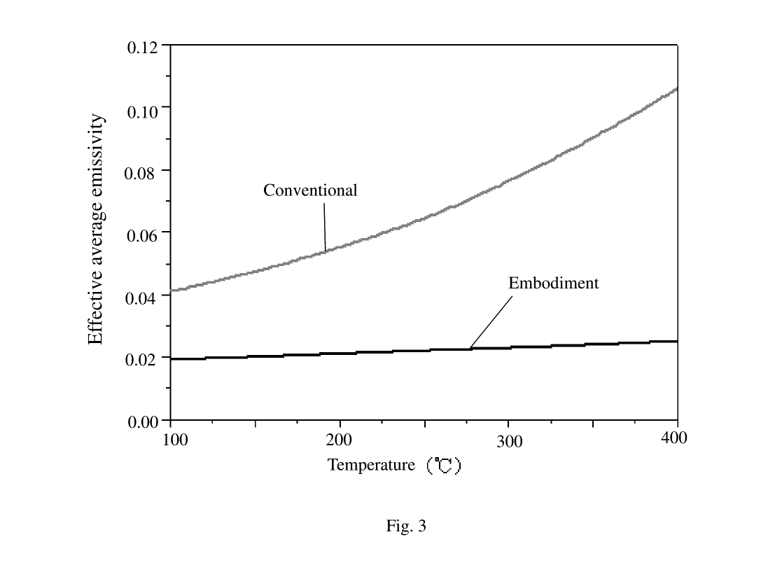

FIG. 3 shows the emissivity curves of a coating of the present embodiment and a conventional selective absorption coating at different temperatures. The infrared emissivity was calculated using the following equation (e.g., at 200° C.):

$$ɛ = {{\int }_{2 µm}}^{48 µm} {E}_{200} ( λ ) [ 1 - R ( λ ) ] d λ / {{\int }_{2 µm}}^{48 µm} {E}_{200} ( λ ) / d λ$$

where E₂₀₀(λ) is the wavelength distribution of 200° C. blackbody radiation (2 μm-48 μm). From FIG. 3, it can be seen that compared to the conventional selective absorption coating, the selective absorption coating of the present embodiment has a lower infrared emissivity; in particular, at high temperature, a much lower infrared emissivity can be obtained.

The calculated absorptance α in the solar spectrum range and infrared emissivity at 200° C. are shown in Table 2.

TABLE 2
Solar spectrum absorptance and infrared emissivity at 200° C.

| | absorptance α in solar | emissivity ε | |
|---|---|---|---|
| Coating sample | spectrum range/% | (200° C.)/% | α/ε |
| Embodiment | 79.0 | 2.1 | 37.6 |
| Conventional | 94.3 | 5.5 | 17.1 |

The solar spectrum absorptance was calculated using the following equation:

$$α = {{\int }_{300 nm}}^{2500 nm} A ( λ ) [ 1 - R ( λ ) ] d λ / {{\int }_{300 nm}}^{2500 nm} A ( λ ) / d λ$$

where A(λ) is the solar radiation illuminance spectrum (W/m²μm) at Air Mass 1.5, and R(λ) is the measured reflection spectrum of the solar spectrum selective absorption coating (0.3-2.5 μm) measured by the spectrophotometer.

In a coating obtained according to the present embodiment having a Ge absorption layer thickness of 25-26 nm, the absorptance α is above 79%, and its emissivity ε at 200° C. is approximately 1.7-2.1%, so the a/c ratio is approximately 37-47, much higher than that of current commercially available coating products. This type of solar spectrum selective absorption coating based on intrinsic absorption of semiconductor Ge is particularly suitable for large-area, medium-temperature solar heat collectors.

The stability in the medium-temperature range and durability of the solar spectrum selective absorption coating in vacuum environments was tested by annealing a coating made by the present embodiment under vacuum conditions. The coating sample was placed under vacuum condition (below 1×10⁻⁵ Torr), heated to 250° C. and annealed for 5 hours. The absorptance and thermal emissivity of the annealed coating sample are slightly changed as compared to before the annealing, but the changes are not significant, and the a/c ratio is in fact increased, so the photothermal conversion efficiency is slightly increased. This shows that the coating of the present embodiment can be applied to medium-temperature solar heat collectors in vacuum conditions.

It will be apparent to those skilled in the art that various modification and variations can be made in the solar spectrum selective absorption coating and its manufacturing method of the present invention without departing from the spirit or scope of the invention. Thus, it is intended that the present invention cover modifications and variations that come within the scope of the appended claims and their equivalents.

What is claimed is:

1. A solar spectrum selective absorption coating, comprising:
a substrate;
an infrared reflective layer on the substrate;
an absorption layer on the infrared reflective layer, made of a thin film of semiconductor germanium; and
an antireflection layer on the absorption layer, made of an inner layer of higher refractive index dielectric and an outer layer of lower refractive index dielectric, the inner layer having a higher refractive index than the outer layer.

2. The solar spectrum selective absorption coating of claim 1, wherein the absorption layer is formed of amorphous germanium, which has a refractive index of 3.4-4.9 and an extinction coefficient is 0.5-3.1 within a wavelength range of 350 nm-980 nm, and a refractive index of 4.1-4.3 and an extinction coefficient of below 0.03 within a wavelength range of 2 μm-25 μm.

3. The solar spectrum selective absorption coating of claim 2, wherein a thickness of the germanium film of the absorption layer is 15-50 nm.

4. The solar spectrum selective absorption coating of claim 1, wherein the infrared reflective layer is made of a metal selected from a group consisting of Al, Cu, Au, Ag, Ni, and Cr.

5. The solar spectrum selective absorption coating of claim 4, wherein a thickness of the metal of the infrared reflective layer is 50-200 nm.

6. The solar spectrum selective absorption coating of claim 1, wherein the infrared reflective layer is made of Al.

7. The solar spectrum selective absorption coating of claim 1, wherein the inner layer of higher refractive index dielectric has a refractive index of n=2.0-3.0 and the outer layer of lower refractive index dielectric has a refractive index of n=1.1-2.0.

8. The solar spectrum selective absorption coating of claim 7, wherein a thickness of the higher refractive index dielectric is 10-60 nm and a thickness of the lower refractive index dielectric is 30-130 nm.

9. The solar spectrum selective absorption coating of claim 7, wherein the higher refractive index dielectric is selected from a group consisting of Bi₂O₃, CeO₂, Nb₂O₅, TeO₂, HfO₂, ZrO₂, Cr₂O₃, Sb₂O₃, Ta₂O₅, Si₃N₄, and TiO₂.

10. The solar spectrum selective absorption coating of claim 7, wherein the higher refractive index dielectric is TiO₂.

11. The solar spectrum selective absorption coating of claim 7, wherein the lower refractive index dielectric is selected from a group consisting of porous SiO₂, Al₂O₃, ThO₂, Dy₂O₃, Eu₂O₃, Gd₂O₃, Y₂O₃, La₂O₃, MgO, Sm₂O₃, and a SiO₂/Al₂O₃ mixture.

12. The solar spectrum selective absorption coating of claim 7, wherein the lower refractive index dielectric is a SiO₂/Al₂O₃ mixture.

13. The solar spectrum selective absorption coating of claim 1, wherein the substrate is made of glass, aluminum, copper, or stainless steel.

14. A method for forming the solar spectrum selective absorption coating of claim 1, the method comprising:
preparing the substrate, including obtaining a polished metal plate or glass plate and applying mechanical cleaning to it followed by RF (radio frequency) Ar plasma cleaning to remove contaminants and oxidized layer on a surface of the substrate;
forming the infrared reflective layer, including using DC (direct current) magnetron sputtering to form a metal infrared reflective layer on the surface of the substrate;
forming the absorption layer, including using DC magnetron sputtering to form the absorption layer on a surface of the infrared reflective layer; and
forming the antireflection layer, including using DC oxidation reactive magnetron sputtering to form the antireflection layer on a surface of the absorption layer.

15. The method of claim 14, wherein a thickness of the substrate is 0.2-10 mm.

16. The method of claim 14, wherein the infrared reflective layer is made of Al and has a thickness of 50-120 nm.

17. The method of claim 14, wherein the absorption layer is formed of amorphous germanium, which has a refractive index of 3.4-4.9 and an extinction coefficient is 0.5-3.1 within a wavelength range of 350 nm-980 nm, and a refractive index of 4.1-4.3 and an extinction coefficient of below 0.03 within a wavelength range of 2 μm-25 μm.

18. The method of claim 14, wherein the antireflection layer includes a layer of higher refractive index dielectric made of TiO₂ and having a thickness of 10 nm-60 nm, and a lower refractive index dielectric made of SiO₂ and having a thickness of 30 nm-130 nm.
